(19) United States
(12) Patent Application Publication
(10) Pub. No.: US 2024/0071902 A1
(43) Pub. Date: Feb. 29, 2024

(54) FOLDED STAIRCASE VIA ROUTING FOR MEMORY

(71) Applicant: Micron Technology, Inc., Boise, ID (US)

(72) Inventors: Shuangqiang Luo, Boise, ID (US); Lifang Xu, Boise, ID (US)

(21) Appl. No.: 17/893,718

(22) Filed: Aug. 23, 2022

(51) Int. Cl. H01L 23/522; H01L 21/768; H01L 27/11519; H01L 27/11524; H01L 27/11551; H01L 27/11565; H01L 27/1157; H01L 27/11578

(52) U.S. Cl. CPC H01L 23/5226; H01L 21/76877; H01L 27/11519; H01L 27/11524; H01L 27/11551; H01L 27/11565; H01L 27/1157; H01L 27/11578

(57) ABSTRACT

Methods, systems, and devices for folded staircase via routing for memory are described. For instance, a memory device may include a set of word lines extending in first direction. Additionally, the memory device may include a first via, a second via, and a third via in a trench that extends through at least a portion of the set of word lines The first via, the second via, and the third via may extend in a second direction different than the first, where the second via is between the first via and the third via along the first direction, and where the second via is coupled with a word line of the set of word lines. Additionally, the first via and the third via may be electrically isolated from the word line of the set of word lines.

### FIELD OF TECHNOLOGY

The following relates to one or more systems for memory, including folded staircase via routing for memory.

### BACKGROUND

Memory devices are widely used to store information in various electronic devices such as computers, user devices, wireless communication devices, cameras, digital displays, and the like. Information is stored by programming memory cells within a memory device to various states. For example, binary memory cells may be programmed to one of two supported states, often corresponding to a logic 1 or a logic 0. In some examples, a single memory cell may support more than two possible states, any one of which may be stored by the memory cell. To access information stored by a memory device, a component may read (e.g., sense, detect, retrieve, identify, determine, evaluate) the state of one or more memory cells within the memory device. To store information, a component may write (e.g., program, set, assign) one or more memory cells within the memory device to corresponding states.

Various types of memory devices exist, including magnetic hard disks, random access memory (RAM), read-only memory (ROM), dynamic RAM (DRAM), synchronous dynamic RAM (SDRAM), static RAM (SRAM), ferroelectric RAM (FeRAM), magnetic RAM (MRAM), resistive RAM (RRAM), flash memory, phase change memory (PCM), 3-dimensional cross-point memory (3D cross point), not-or (NOR) and not-and (NAND) memory devices, and others. Memory devices may be described in terms of volatile configurations or non-volatile configurations. Volatile memory cells (e.g., DRAM) may lose their programmed states over time unless they are periodically refreshed by an external power source. Non-volatile memory cells (e.g., NAND) may maintain their programmed states for extended periods of time even in the absence of an external power source.

### BRIEF DESCRIPTION OF THE DRAWINGS

FIG. 1 illustrates an example of a system that supports folded staircase via routing for memory in accordance with examples as disclosed herein.

FIG. 2 illustrates an example of a system that supports folded staircase via routing for memory in accordance with examples as disclosed herein.

FIGS. 3A and 3B illustrate examples of memory array trench schemes that support folded staircase via routing for memory in accordance with examples as disclosed herein.

FIG. 4 illustrates an example of a memory array trench diagram that supports folded staircase via routing for memory in accordance with examples as disclosed herein.

FIG. 5 illustrates an example of a memory array trench scheme that supports folded staircase via routing for memory in accordance with examples as disclosed herein.

FIG. 6 shows a block diagram of a memory device that supports folded staircase via routing for memory in accordance with examples as disclosed herein.

FIG. 7 shows a flowchart illustrating a method or methods that support folded staircase via routing for memory in accordance with examples as disclosed herein.

### DETAILED DESCRIPTION

A memory array may include a set of trenches that run through the memory array along a first direction, where each trench of the set of trenches may include a floor and two walls on opposite sides of the floor. In some examples, each trench of the set of trenches may include a set of vias that penetrate (e.g., at least partially go below) a surface of the trench. For instance, each trench may include a first via that penetrates a first wall of the trench, a second via that penetrates the floor of the trench, and a third via that penetrates the second wall of the trench. The first and third vias (e.g., respective vias that each penetrate a respective wall of a trench) may be referred to as outer vias and the second via (e.g., a via that penetrates the floor of the trench) may be referred to as an inner via. In some examples, a first and second contact may be present on the floor of the trench, where the first contact may be coupled with (e.g., electrically coupled with) the first via and the second contact may be coupled with (e.g., electrically coupled with) the third via (e.g., the first contact and the second contact may be coupled with the outer vias).

In some examples, the first, second, and third vias may be at least partially surrounded by a first material (e.g., a dielectric material). Additionally, the walls of the trench may be coated in a second material (e.g., an oxide material, such as a non-thermal oxide material) and the floor of the trench may not be coated in the second material. In some sections, the second material may at least partially block the first material, which may lead to the thickness of the first material at this section being thinner relative to the remaining portion of the first material. Accordingly, the electric field may differ at this portion of the first material and, accordingly, this portion of the first material may break down quicker than the remaining portion of the first material. In order to decrease the electric field at this portion of the first material, the overall thickness of the first material may be increased. However, as a thickness of the first material on the first, second, and third vias increases, a likelihood that the first via and the third via are able to penetrate the walls of the trench may decrease (e.g., due to an interaction between the first material and the second material).

In order to enable the first and third vias to penetrate the wall of the trench while mitigating the effects of the interaction between the first and second material, the first and third vias may retain a quantity of the first material such that the first and third vias may penetrate the walls of the trench, but may also be isolated from the first contact and the second contact. The second via may be coupled with one of the first contact and the second contact. As the second via penetrates the floor of the trench, the second via may be configured not to interact with (e.g., may be configured to be isolated with respect to) the wall of the trench. Accordingly, a quantity of the first material surrounding the second via may be greater than the quantity of the first material associated with the first via and the third via. The other of the first contact and the second contact may be coupled with another inner via within the trench. Coupling the second via with the one of the first contact and the second contact may have advantages as compared to coupling the first contact or the second contact with the first via or the second via. For instance, as the first material surrounding the second via does not interact with the wall of the trench, a thickness still enabling of trench penetration may be used for the first material surrounding the second via while still meeting an electrical field constraint (e.g., having an electrical field within the first material below a threshold amount). Additionally, as the first and third vias are not coupled with the first or second contacts, early breakdown of the first materials surrounding the first and third vias may not affect signals at the first and second contacts.

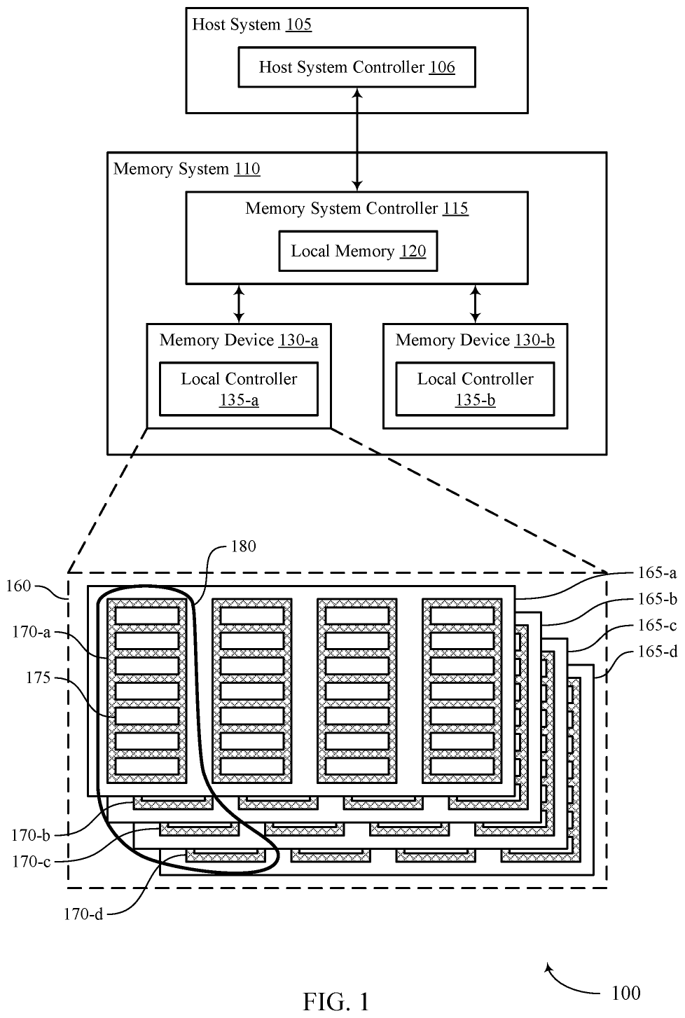

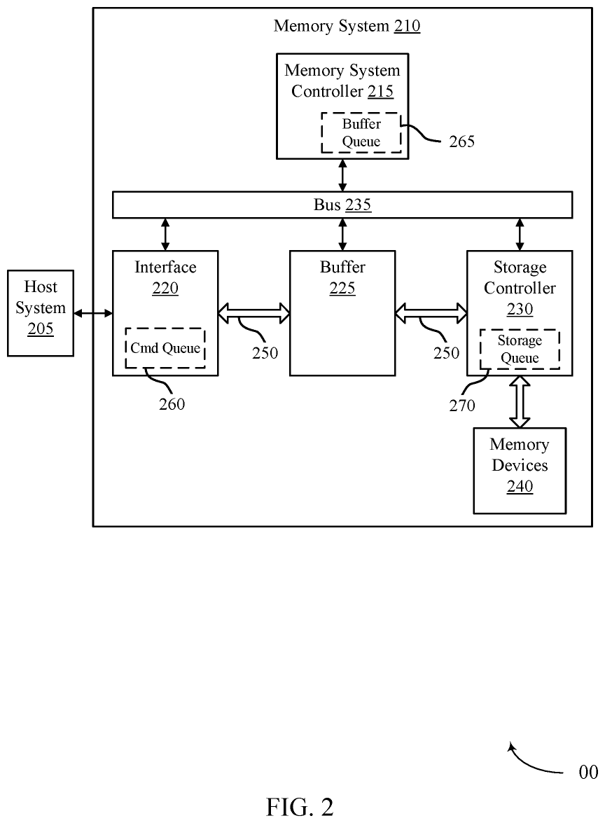

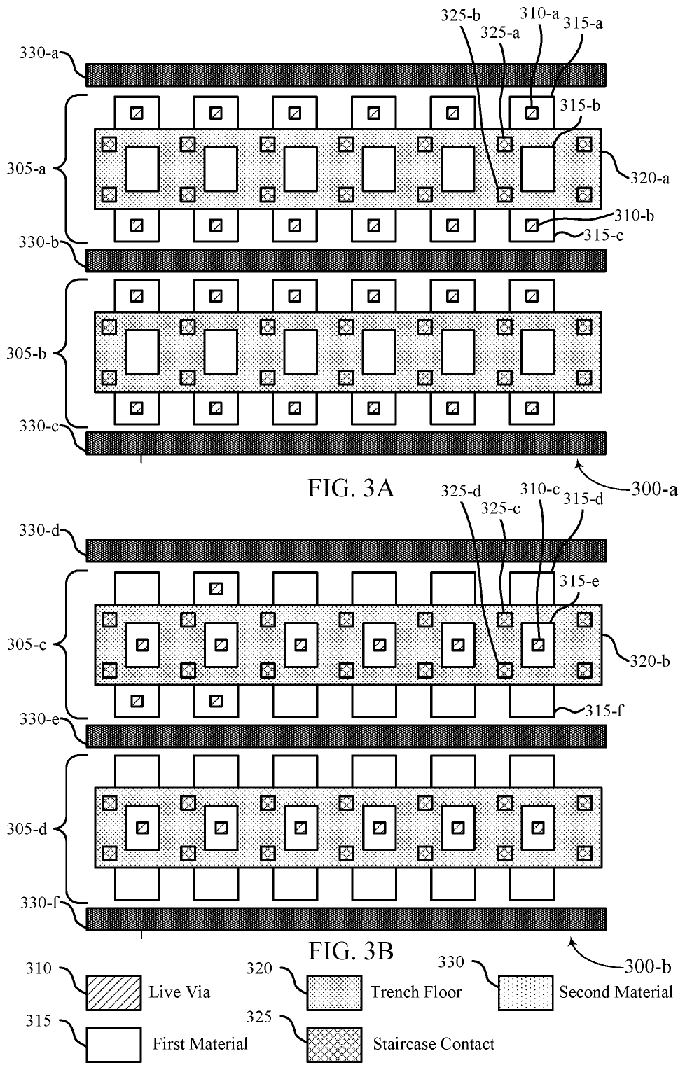

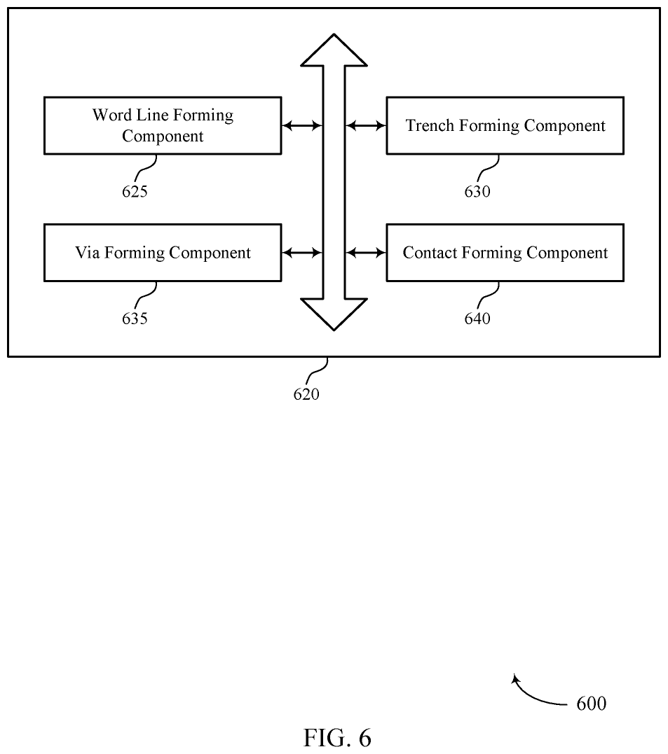

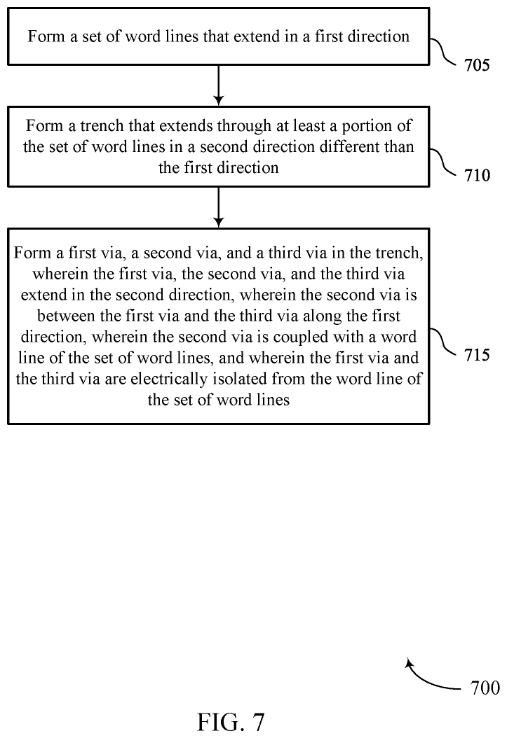

Features of the disclosure are initially described in the context of systems, devices, and circuits with reference to FIGS. 1 through 2. Features of the disclosure are described in the context of memory array trench schemes and a memory array trench diagram with reference to FIGS. 3 through 5. These and other features of the disclosure are further illustrated by and described in the context of an apparatus diagram and flowchart that relate to folded staircase via routing for memory with reference to FIGS. 6 and 7.

FIG. 1 illustrates an example of a system 100 that supports folded staircase via routing for memory in accordance with examples as disclosed herein. The system 100 includes a host system 105 coupled with a memory system 110.

A memory system 110 may be or include any device or collection of devices, where the device or collection of devices includes at least one memory array. For example, a memory system 110 may be or include a Universal Flash Storage (UFS) device, an embedded Multi-Media Controller (eMMC) device, a flash device, a universal serial bus (USB) flash device, a secure digital (SD) card, a solid-state drive (SSD), a hard disk drive (HDD), a dual in-line memory module (DIMM), a small outline DIMM (SO-DIMM), or a non-volatile DIMM (NVDIMM), among other possibilities.

The system 100 may be included in a computing device such as a desktop computer, a laptop computer, a network server, a mobile device, a vehicle (e.g., airplane, drone, train, automobile, or other conveyance), an Internet of Things (IoT) enabled device, an embedded computer (e.g., one included in a vehicle, industrial equipment, or a networked commercial device), or any other computing device that includes memory and a processing device.

The system 100 may include a host system 105, which may be coupled with the memory system 110. In some examples, this coupling may include an interface with a host system controller 106, which may be an example of a controller or control component configured to cause the host system 105 to perform various operations in accordance with examples as described herein. The host system 105 may include one or more devices and, in some cases, may include a processor chipset and a software stack executed by the processor chipset. For example, the host system 105 may include an application configured for communicating with the memory system 110 or a device therein. The processor chipset may include one or more cores, one or more caches (e.g., memory local to or included in the host system 105), a memory controller (e.g., NVDIMM controller), and a storage protocol controller (e.g., peripheral component interconnect express (PCIe) controller, serial advanced technology attachment (SATA) controller). The host system 105 may use the memory system 110, for example, to write data to the memory system 110 and read data from the memory system 110. Although one memory system 110 is shown in FIG. 1, the host system 105 may be coupled with any quantity of memory systems 110.

The host system 105 may be coupled with the memory system 110 via at least one physical host interface. The host system 105 and the memory system 110 may, in some cases, be configured to communicate via a physical host interface using an associated protocol (e.g., to exchange or otherwise communicate control, address, data, and other signals between the memory system 110 and the host system 105). Examples of a physical host interface may include, but are not limited to, a SATA interface, a UFS interface, an eMMC interface, a PCIe interface, a USB interface, a Fiber Channel interface, a Small Computer System Interface (SCSI), a Serial Attached SCSI (SAS), a Double Data Rate (DDR) interface, a DIMM interface (e.g., DIMM socket interface that supports DDR), an Open NAND Flash Interface (ONFI), and a Low Power Double Data Rate (LPDDR) interface. In some examples, one or more such interfaces may be included in or otherwise supported between a host system controller 106 of the host system 105 and a memory system controller 115 of the memory system 110. In some examples, the host system 105 may be coupled with the memory system 110 (e.g., the host system controller 106 may be coupled with the memory system controller 115) via a respective physical host interface for each memory device 130 included in the memory system 110, or via a respective physical host interface for each type of memory device 130 included in the memory system 110.

The memory system 110 may include a memory system controller 115 and one or more memory devices 130. A memory device 130 may include one or more memory arrays of any type of memory cells (e.g., non-volatile memory cells, volatile memory cells, or any combination thereof). Although two memory devices 130-a and 130-b are shown in the example of FIG. 1, the memory system 110 may include any quantity of memory devices 130. Further, if the memory system 110 includes more than one memory device 130, different memory devices 130 within the memory system 110 may include the same or different types of memory cells.

The memory system controller 115 may be coupled with and communicate with the host system 105 (e.g., via the physical host interface) and may be an example of a controller or control component configured to cause the memory system 110 to perform various operations in accordance with examples as described herein. The memory system controller 115 may also be coupled with and communicate with memory devices 130 to perform operations such as reading data, writing data, erasing data, or refreshing data at a memory device 130—among other such operations—which may generically be referred to as access operations. In some cases, the memory system controller 115 may receive commands from the host system 105 and communicate with one or more memory devices 130 to execute such commands (e.g., at memory arrays within the one or more memory devices 130). For example, the memory system controller 115 may receive commands or operations from the host system 105 and may convert the commands or operations into instructions or appropriate commands to achieve the desired access of the memory devices 130. In some cases, the memory system controller 115 may exchange data with the host system 105 and with one or more memory devices 130 (e.g., in response to or otherwise in association with commands from the host system 105). For example, the memory system controller 115 may convert responses (e.g., data packets or other signals) associated with the memory devices 130 into corresponding signals for the host system 105.

The memory system controller 115 may be configured for other operations associated with the memory devices 130. For example, the memory system controller 115 may execute or manage operations such as wear-leveling operations, garbage collection operations, error control operations such as error-detecting operations or error-correcting operations, encryption operations, caching operations, media management operations, background refresh, health monitoring, and address translations between logical addresses (e.g., logical block addresses (LBAs)) associated with commands from the host system 105 and physical addresses (e.g., physical block addresses) associated with memory cells within the memory devices 130.

The memory system controller 115 may include hardware such as one or more integrated circuits or discrete components, a buffer memory, or a combination thereof. The hardware may include circuitry with dedicated (e.g., hard-coded) logic to perform the operations ascribed herein to the memory system controller 115. The memory system controller 115 may be or include a microcontroller, special purpose logic circuitry (e.g., a field programmable gate array (FPGA), an application specific integrated circuit (ASIC), a digital signal processor (DSP)), or any other suitable processor or processing circuitry.

The memory system controller 115 may also include a local memory 120. In some cases, the local memory 120 may include read-only memory (ROM) or other memory that may store operating code (e.g., executable instructions) executable by the memory system controller 115 to perform functions ascribed herein to the memory system controller 115. In some cases, the local memory 120 may additionally, or alternatively, include static random access memory (SRAM) or other memory that may be used by the memory system controller 115 for internal storage or calculations, for example, related to the functions ascribed herein to the memory system controller 115. Additionally, or alternatively, the local memory 120 may serve as a cache for the memory system controller 115. For example, data may be stored in the local memory 120 if read from or written to a memory device 130, and the data may be available within the local memory 120 for subsequent retrieval for or manipulation (e.g., updating) by the host system 105 (e.g., with reduced latency relative to a memory device 130) in accordance with a cache policy.

Although the example of the memory system 110 in FIG. 1 has been illustrated as including the memory system controller 115, in some cases, a memory system 110 may not include a memory system controller 115. For example, the memory system 110 may additionally, or alternatively, rely on an external controller (e.g., implemented by the host system 105) or one or more local controllers 135, which may be internal to memory devices 130, respectively, to perform the functions ascribed herein to the memory system controller 115. In general, one or more functions ascribed herein to the memory system controller 115 may, in some cases, be performed instead by the host system 105, a local controller 135, or any combination thereof. In some cases, a memory device 130 that is managed at least in part by a memory system controller 115 may be referred to as a managed memory device. An example of a managed memory device is a managed NAND (MNAND) device.

A memory device 130 may include one or more arrays of non-volatile memory cells. For example, a memory device 130 may include NAND (e.g., NAND flash) memory, ROM, phase change memory (PCM), self-selecting memory, other chalcogenide-based memories, ferroelectric random access memory (RAM) (FeRAM), magneto RAM (MRAM), NOR (e.g., NOR flash) memory, Spin Transfer Torque (STT)-MRAM, conductive bridging RAM (CBRAM), resistive random access memory (RRAM), oxide based RRAM (OxRAM), electrically erasable programmable ROM (EEPROM), or any combination thereof.

Additionally, or alternatively, a memory device 130 may include one or more arrays of volatile memory cells. For example, a memory device 130 may include RAM memory cells, such as dynamic RAM (DRAM) memory cells and synchronous DRAM (SDRAM) memory cells.

In some examples, a memory device 130 may include (e.g., on a same die or within a same package) a local controller 135, which may execute operations on one or more memory cells of the respective memory device 130. A local controller 135 may operate in conjunction with a memory system controller 115 or may perform one or more functions ascribed herein to the memory system controller 115. For example, as illustrated in FIG. 1, a memory device 130-a may include a local controller 135-a and a memory device 130-b may include a local controller 135-b.

In some cases, a memory device 130 may be or include a NAND device (e.g., NAND flash device). A memory device 130 may be or include a die 160 (e.g., a memory die). For example, in some cases, a memory device 130 may be a package that includes one or more dies 160. A die 160 may, in some examples, be a piece of electronics-grade semiconductor cut from a wafer (e.g., a silicon die cut from a silicon wafer). Each die 160 may include one or more planes 165, and each plane 165 may include a respective set of blocks 170, where each block 170 may include a respective set of pages 175, and each page 175 may include a set of memory cells.

In some cases, a NAND memory device 130 may include memory cells configured to each store one bit of information, which may be referred to as single level cells (SLCs). Additionally, or alternatively, a NAND memory device 130 may include memory cells configured to each store multiple bits of information, which may be referred to as multi-level cells (MLCs) if configured to each store two bits of information, as tri-level cells (TLCs) if configured to each store three bits of information, as quad-level cells (QLCs) if configured to each store four bits of information, or more generically as multiple-level memory cells. Multiple-level memory cells may provide greater density of storage relative to SLC memory cells but may, in some cases, involve narrower read or write margins or greater complexities for supporting circuitry.

In some cases, planes 165 may refer to groups of blocks 170, and in some cases, concurrent operations may be performed on different planes 165. For example, concurrent operations may be performed on memory cells within different blocks 170 so long as the different blocks 170 are in different planes 165. In some cases, an individual block 170 may be referred to as a physical block, and a virtual block 180 may refer to a group of blocks 170 within which concurrent operations may occur. For example, concurrent operations may be performed on blocks 170-a, 170-b, 170-c, and 170-d that are within planes 165-a, 165-b, 165-c, and 165-d, respectively, and blocks 170-a, 170-b, 170-c, and 170-d may be collectively referred to as a virtual block 180. In some cases, a virtual block may include blocks 170 from different memory devices 130 (e.g., including blocks in one or more planes of memory device 130-a and memory device 130-b). In some cases, the blocks 170 within a virtual block may have the same block address within their respective planes 165 (e.g., block 170-a may be “block 0” of plane 165-a, block 170-b may be “block 0” of plane 165-b, and so on). In some cases, performing concurrent operations in different planes 165 may be subject to one or more restrictions, such as concurrent operations being performed on memory cells within different pages 175 that have the same page address within their respective planes 165 (e.g., related to command decoding, page address decoding circuitry, or other circuitry being shared across planes 165).

In some cases, a block 170 may include memory cells organized into rows (pages 175) and columns (e.g., strings, not shown). For example, memory cells in a same page 175 may share (e.g., be coupled with) a common word line, and memory cells in a same string may share (e.g., be coupled with) a common digit line (which may alternatively be referred to as a bit line).

For some NAND architectures, memory cells may be read and programmed (e.g., written) at a first level of granularity (e.g., at the page level of granularity) but may be erased at a second level of granularity (e.g., at the block level of granularity). That is, a page 175 may be the smallest unit of memory (e.g., set of memory cells) that may be independently programmed or read (e.g., programed or read concurrently as part of a single program or read operation), and a block 170 may be the smallest unit of memory (e.g., set of memory cells) that may be independently erased (e.g., erased concurrently as part of a single erase operation). Further, in some cases, NAND memory cells may be erased before they can be re-written with new data. Thus, for example, a used page 175 may, in some cases, not be updated until the entire block 170 that includes the page 175 has been erased.

In some cases, to update some data within a block 170 while retaining other data within the block 170, the memory device 130 may copy the data to be retained to a new block 170 and write the updated data to one or more remaining pages of the new block 170. The memory device 130 (e.g., the local controller 135) or the memory system controller 115 may mark or otherwise designate the data that remains in the old block 170 as invalid or obsolete and may update a logical-to-physical (L2P) mapping table to associate the logical address (e.g., LBA) for the data with the new, valid block 170 rather than the old, invalid block 170. In some cases, such copying and remapping may be performed instead of erasing and rewriting the entire old block 170 due to latency or wearout considerations, for example. In some cases, one or more copies of an L2P mapping table may be stored within the memory cells of the memory device 130 (e.g., within one or more blocks 170 or planes 165) for use (e.g., reference and updating) by the local controller 135 or memory system controller 115.

In some cases, L2P mapping tables may be maintained and data may be marked as valid or invalid at the page level of granularity, and a page 175 may contain valid data, invalid data, or no data. Invalid data may be data that is outdated due to a more recent or updated version of the data being stored in a different page 175 of the memory device 130. Invalid data may have been previously programmed to the invalid page 175 but may no longer be associated with a valid logical address, such as a logical address referenced by the host system 105. Valid data may be the most recent version of such data being stored on the memory device 130. A page 175 that includes no data may be a page 175 that has never been written to or that has been erased.

In some cases, a memory system controller 115 or a local controller 135 may perform operations (e.g., as part of one or more media management algorithms) for a memory device 130, such as wear leveling, background refresh, garbage collection, scrub, block scans, health monitoring, or others, or any combination thereof. For example, within a memory device 130, a block 170 may have some pages 175 containing valid data and some pages 175 containing invalid data. To avoid waiting for all of the pages 175 in the block 170 to have invalid data in order to erase and reuse the block 170, an algorithm referred to as “garbage collection” may be invoked to allow the block 170 to be erased and released as a free block for subsequent write operations. Garbage collection may refer to a set of media management operations that include, for example, selecting a block 170 that contains valid and invalid data, selecting pages 175 in the block that contain valid data, copying the valid data from the selected pages 175 to new locations (e.g., free pages 175 in another block 170), marking the data in the previously selected pages 175 as invalid, and erasing the selected block 170. As a result, the quantity of blocks 170 that have been erased may be increased such that more blocks 170 are available to store subsequent data (e.g., data subsequently received from the host system 105).

In some cases, a memory system 110 may utilize a memory system controller 115 to provide a managed memory system that may include, for example, one or more memory arrays and related circuitry combined with a local (e.g., on-die or in-package) controller (e.g., local controller 135). An example of a managed memory system is a managed NAND (MNAND) system.

The system 100 may include any quantity of non-transitory computer readable media that support folded staircase via routing for memory. For example, the host system 105 (e.g., a host system controller 106), the memory system 110 (e.g., a memory system controller 115), or a memory device 130 (e.g., a local controller 135) may include or otherwise may access one or more non-transitory computer readable media storing instructions (e.g., firmware, logic, code) for performing the functions ascribed herein to the host system 105, the memory system 110, or a memory device 130. For example, such instructions, if executed by the host system 105 (e.g., by a host system controller 106), by the memory system 110 (e.g., by a memory system controller 115), or by a memory device 130 (e.g., by a local controller 135), may cause the host system 105, the memory system 110, or the memory device 130 to perform associated functions as described herein.

A memory array of the memory device 130 may include a set of trenches that run through the memory array along a first direction, where each trench of the set of trenches may include a floor and two walls on opposite sides of the floor. In some examples, each trench of the set of trenches may include a set of vias that penetrate (e.g., at least partially go below) a surface of the trench. For instance, each trench may include a first via that penetrates a first wall of the trench, a second via that penetrates the floor of the trench, and a third via that penetrates the second wall of the trench. The first and third vias (e.g., respective vias that each penetrate a respective wall of a trench) may be referred to as outer vias and the second via (e.g., a via that penetrates the floor of the trench) may be referred to as an inner via. In some examples, a first and second contact may be present on the floor of the trench, where the first contact may be coupled with (e.g., electrically coupled with) the first via and the second contact may be coupled with (e.g., electrically coupled with) the third via (e.g., the first contact and the second contact may be coupled with the outer vias).

In some examples, the first, second, and third vias may be at least partially surrounded by a first material (e.g., a dielectric material). Additionally, the walls of the trench may be coated in a second material (e.g., an oxide material, such as a non-thermal oxide material) and the floor of the trench may not be coated in the second material. In some sections, the second material may at least partially block the first material, which may lead to the thickness of the first material at this section being thinner relative to the remaining portion of the first material. Accordingly, the electric field may differ at this portion of the first material and, accordingly, this portion of the first material may break down quicker than the remaining portion of the first material. In order to decrease the electric field at this portion of the first material, the overall thickness of the first material may be increased. However, as a thickness of the first material on the first, second, and third vias increases, a likelihood that the first via and the third via are able to penetrate the walls of the trench may decrease (e.g., due to an interaction between the first material and the second material).

In order to enable the first and third vias to penetrate the wall of the trench while mitigating the effects of the interaction between the first and second material, the first and third vias may retain a quantity of the first material such that the first and third vias may penetrate the walls of the trench, but may also be isolated from the first contact and the second contact. The second via may be coupled with one of the first contact and the second contact. As the second via penetrates the floor of the trench, the second via may be configured not to interact with (e.g., may be configured to be isolated with respect to) the wall of the trench. Accordingly, a quantity of the first material surrounding the second via may be greater than the quantity of the first material associated with the first via and the third via. The other of the first contact and the second contact may be coupled with another inner via within the trench. Coupling the second via with the one of the first contact and the second contact may have advantages as compared to coupling the first contact or the second contact with the first via or the second via. For instance, as the first material surrounding the second via does not interact with the wall of the trench, a thickness still enabling of trench penetration may be used for the first material surrounding the second via while still meeting an electrical field constraint (e.g., having an electrical field within the first material below a threshold amount). Additionally, as the first and third vias are not coupled with the first or second contacts, early breakdown of the first materials surrounding the first and third vias may not affect signals at the first and second contacts.

FIG. 2 illustrates an example of a system 200 that supports folded staircase via routing for memory in accordance with examples as disclosed herein. The system 200 may be an example of a system 100 as described with reference to FIG. 1, or aspects thereof. The system 200 may include a memory system 210 configured to store data received from the host system 205 and to send data to the host system 205, if requested by the host system 205 using access commands (e.g., read commands or write commands). The system 200 may implement aspects of the system 100 as described with reference to FIG. 1. For example, the memory system 210 and the host system 205 may be examples of the memory system 110 and the host system 105, respectively.

The memory system 210 may include one or more memory devices 240 to store data transferred between the memory system 210 and the host system 205 (e.g., in response to receiving access commands from the host system 205). The memory devices 240 may include one or more memory devices as described with reference to FIG. 1. For example, the memory devices 240 may include NAND memory, PCM, self-selecting memory, 3D cross point or other chalcogenide-based memories, FERAM, MRAM, NOR (e.g., NOR flash) memory, STT-MRAM, CBRAM, RRAM, or OxRAM, among other examples.

The memory system 210 may include a storage controller 230 for controlling the passing of data directly to and from the memory devices 240 (e.g., for storing data, for retrieving data, for determining memory locations in which to store data and from which to retrieve data). The storage controller 230 may communicate with memory devices 240 directly or via a bus (not shown), which may include using a protocol specific to each type of memory device 240. In some cases, a single storage controller 230 may be used to control multiple memory devices 240 of the same or different types. In some cases, the memory system 210 may include multiple storage controllers 230 (e.g., a different storage controller 230 for each type of memory device 240). In some cases, a storage controller 230 may implement aspects of a local controller 135 as described with reference to FIG. 1.

The memory system 210 may include an interface 220 for communication with the host system 205, and a buffer 225 for temporary storage of data being transferred between the host system 205 and the memory devices 240. The interface 220, buffer 225, and storage controller 230 may support translating data between the host system 205 and the memory devices 240 (e.g., as shown by a data path 250), and may be collectively referred to as data path components.

Using the buffer 225 to temporarily store data during transfers may allow data to be buffered while commands are being processed, which may reduce latency between commands and may support arbitrary data sizes associated with commands. This may also allow bursts of commands to be handled, and the buffered data may be stored, or transmitted, or both (e.g., after a burst has stopped). The buffer 225 may include relatively fast memory (e.g., some types of volatile memory, such as SRAM or DRAM), or hardware accelerators, or both to allow fast storage and retrieval of data to and from the buffer 225. The buffer 225 may include data path switching components for bi-directional data transfer between the buffer 225 and other components.

A temporary storage of data within a buffer 225 may refer to the storage of data in the buffer 225 during the execution of access commands. For example, after completion of an access command, the associated data may no longer be maintained in the buffer 225 (e.g., may be overwritten with data for additional access commands). In some examples, the buffer 225 may be a non-cache buffer. For example, data may not be read directly from the buffer 225 by the host system 205. In some examples, read commands may be added to a queue without an operation to match the address to addresses already in the buffer 225 (e.g., without a cache address match or lookup operation).

The memory system 210 also may include a memory system controller 215 for executing the commands received from the host system 205, which may include controlling the data path components for the moving of the data. The memory system controller 215 may be an example of the memory system controller 115 as described with reference to FIG. 1. A bus 235 may be used to communicate between the system components.

In some cases, one or more queues (e.g., a command queue 260, a buffer queue 265, a storage queue 270) may be used to control the processing of access commands and the movement of corresponding data. This may be beneficial, for example, if more than one access command from the host system 205 is processed concurrently by the memory system 210. The command queue 260, buffer queue 265, and storage queue 270 are depicted at the interface 220, memory system controller 215, and storage controller 230, respectively, as examples of a possible implementation. However, queues, if implemented, may be positioned anywhere within the memory system 210.

Data transferred between the host system 205 and the memory devices 240 may be conveyed along a different path in the memory system 210 than non-data information (e.g., commands, status information). For example, the system components in the memory system 210 may communicate with each other using a bus 235, while the data may use the data path 250 through the data path components instead of the bus 235. The memory system controller 215 may control how and if data is transferred between the host system 205 and the memory devices 240 by communicating with the data path components over the bus 235 (e.g., using a protocol specific to the memory system 210).

If a host system 205 transmits access commands to the memory system 210, the commands may be received by the interface 220 (e.g., according to a protocol, such as a UFS protocol or an eMMC protocol). Thus, the interface 220 may be considered a front end of the memory system 210. After receipt of each access command, the interface 220 may communicate the command to the memory system controller 215 (e.g., via the bus 235). In some cases, each command may be added to a command queue 260 by the interface 220 to communicate the command to the memory system controller 215.

The memory system controller 215 may determine that an access command has been received based on the communication from the interface 220. In some cases, the memory system controller 215 may determine the access command has been received by retrieving the command from the command queue 260. The command may be removed from the command queue 260 after it has been retrieved (e.g., by the memory system controller 215). In some cases, the memory system controller 215 may cause the interface 220 (e.g., via the bus 235) to remove the command from the command queue 260.

After a determination that an access command has been received, the memory system controller 215 may execute the access command. For a read command, this may include obtaining data from one or more memory devices 240 and transmitting the data to the host system 205. For a write command, this may include receiving data from the host system 205 and moving the data to one or more memory devices 240. In either case, the memory system controller 215 may use the buffer 225 for, among other things, temporary storage of the data being received from or sent to the host system 205. The buffer 225 may be considered a middle end of the memory system 210. In some cases, buffer address management (e.g., pointers to address locations in the buffer 225) may be performed by hardware (e.g., dedicated circuits) in the interface 220, buffer 225, or storage controller 230.

To process a write command received from the host system 205, the memory system controller 215 may determine if the buffer 225 has sufficient available space to store the data associated with the command. For example, the memory system controller 215 may determine (e.g., via firmware, via controller firmware), an amount of space within the buffer 225 that may be available to store data associated with the write command.

In some cases, a buffer queue 265 may be used to control a flow of commands associated with data stored in the buffer 225, including write commands. The buffer queue 265 may include the access commands associated with data currently stored in the buffer 225. In some cases, the commands in the command queue 260 may be moved to the buffer queue 265 by the memory system controller 215 and may remain in the buffer queue 265 while the associated data is stored in the buffer 225. In some cases, each command in the buffer queue 265 may be associated with an address at the buffer 225. For example, pointers may be maintained that indicate where in the buffer 225 the data associated with each command is stored. Using the buffer queue 265, multiple access commands may be received sequentially from the host system 205 and at least portions of the access commands may be processed concurrently.

If the buffer 225 has sufficient space to store the write data, the memory system controller 215 may cause the interface 220 to transmit an indication of availability to the host system 205 (e.g., a “ready to transfer” indication), which may be performed in accordance with a protocol (e.g., a UFS protocol, an eMMC protocol). As the interface 220 receives the data associated with the write command from the host system 205, the interface 220 may transfer the data to the buffer 225 for temporary storage using the data path 250. In some cases, the interface 220 may obtain (e.g., from the buffer 225, from the buffer queue 265) the location within the buffer 225 to store the data. The interface 220 may indicate to the memory system controller 215 (e.g., via the bus 235) if the data transfer to the buffer 225 has been completed.

After the write data has been stored in the buffer 225 by the interface 220, the data may be transferred out of the buffer 225 and stored in a memory device 240, which may involve operations of the storage controller 230. For example, the memory system controller 215 may cause the storage controller 230 to retrieve the data from the buffer 225 using the data path 250 and transfer the data to a memory device 240. The storage controller 230 may be considered a back end of the memory system 210. The storage controller 230 may indicate to the memory system controller 215 (e.g., via the bus 235) that the data transfer to one or more memory devices 240 has been completed.

In some cases, a storage queue 270 may support a transfer of write data. For example, the memory system controller 215 may push (e.g., via the bus 235) write commands from the buffer queue 265 to the storage queue 270 for processing. The storage queue 270 may include entries for each access command. In some examples, the storage queue 270 may additionally include a buffer pointer (e.g., an address) that may indicate where in the buffer 225 the data associated with the command is stored and a storage pointer (e.g., an address) that may indicate the location in the memory devices 240 associated with the data. In some cases, the storage controller 230 may obtain (e.g., from the buffer 225, from the buffer queue 265, from the storage queue 270) the location within the buffer 225 from which to obtain the data. The storage controller 230 may manage the locations within the memory devices 240 to store the data (e.g., performing wear-leveling, performing garbage collection). The entries may be added to the storage queue 270 (e.g., by the memory system controller 215). The entries may be removed from the storage queue 270 (e.g., by the storage controller 230, by the memory system controller 215) after completion of the transfer of the data.

To process a read command received from the host system 205, the memory system controller 215 may determine if the buffer 225 has sufficient available space to store the data associated with the command. For example, the memory system controller 215 may determine (e.g., via firmware, via controller firmware), an amount of space within the buffer 225 that may be available to store data associated with the read command.

In some cases, the buffer queue 265 may support buffer storage of data associated with read commands in a similar manner as discussed with respect to write commands. For example, if the buffer 225 has sufficient space to store the read data, the memory system controller 215 may cause the storage controller 230 to retrieve the data associated with the read command from a memory device 240 and store the data in the buffer 225 for temporary storage using the data path 250. The storage controller 230 may indicate to the memory system controller 215 (e.g., via the bus 235) when the data transfer to the buffer 225 has been completed.

In some cases, the storage queue 270 may be used to aid with the transfer of read data. For example, the memory system controller 215 may push the read command to the storage queue 270 for processing. In some cases, the storage controller 230 may obtain (e.g., from the buffer 225, from the storage queue 270) the location within one or more memory devices 240 from which to retrieve the data. In some cases, the storage controller 230 may obtain (e.g., from the buffer queue 265) the location within the buffer 225 to store the data. In some cases, the storage controller 230 may obtain (e.g., from the storage queue 270) the location within the buffer 225 to store the data. In some cases, the memory system controller 215 may move the command processed by the storage queue 270 back to the command queue 260.

Once the data has been stored in the buffer 225 by the storage controller 230, the data may be transferred from the buffer 225 and sent to the host system 205. For example, the memory system controller 215 may cause the interface 220 to retrieve the data from the buffer 225 using the data path 250 and transmit the data to the host system 205 (e.g., according to a protocol, such as a UFS protocol or an eMMC protocol). For example, the interface 220 may process the command from the command queue 260 and may indicate to the memory system controller 215 (e.g., via the bus 235) that the data transmission to the host system 205 has been completed.

The memory system controller 215 may execute received commands according to an order (e.g., a first-in-first-out order, according to the order of the command queue 260). For each command, the memory system controller 215 may cause data corresponding to the command to be moved into and out of the buffer 225, as discussed herein. As the data is moved into and stored within the buffer 225, the command may remain in the buffer queue 265. A command may be removed from the buffer queue 265 (e.g., by the memory system controller 215) if the processing of the command has been completed (e.g., if data corresponding to the access command has been transferred out of the buffer 225). If a command is removed from the buffer queue 265, the address previously storing the data associated with that command may be available to store data associated with a new command.

In some examples, the memory system controller 215 may be configured for operations associated with one or more memory devices 240. For example, the memory system controller 215 may execute or manage operations such as wear-leveling operations, garbage collection operations, error control operations such as error-detecting operations or error-correcting operations, encryption operations, caching operations, media management operations, background refresh, health monitoring, and address translations between logical addresses (e.g., LBAs) associated with commands from the host system 205 and physical addresses (e.g., physical block addresses) associated with memory cells within the memory devices 240. For example, the host system 205 may issue commands indicating one or more LBAs and the memory system controller 215 may identify one or more physical block addresses indicated by the LBAs. In some cases, one or more contiguous LBAs may correspond to noncontiguous physical block addresses. In some cases, the storage controller 230 may be configured to perform one or more of the described operations in conjunction with or instead of the memory system controller 215. In some cases, the memory system controller 215 may perform the functions of the storage controller 230 and the storage controller 230 may be omitted.

A memory array of the memory system 210 may include a set of trenches that run through the memory array along a first direction, where each trench of the set of trenches may include a floor and two walls on opposite sides of the floor. In some examples, each trench of the set of trenches may include a set of vias that penetrate (e.g., at least partially go below) a surface of the trench. For instance, each trench may include a first via that penetrates a first wall of the trench, a second via that penetrates the floor of the trench, and a third via that penetrates the second wall of the trench. The first and third vias (e.g., respective vias that each penetrate a respective wall of a trench) may be referred to as outer vias and the second via (e.g., a via that penetrates the floor of the trench) may be referred to as an inner via. In some examples, a first and second contact may be present on the floor of the trench, where the first contact may be coupled with (e.g., electrically coupled with) the first via and the second contact may be coupled with (e.g., electrically coupled with) the third via (e.g., the first contact and the second contact may be coupled with the outer vias).

In some examples, the first, second, and third vias may be at least partially surrounded by a first material (e.g., a dielectric material). Additionally, the walls of the trench may be coated in a second material (e.g., an oxide material, such as a non-thermal oxide material) and the floor of the trench may not be coated in the second material. In some sections, the second material may at least partially block the first material, which may lead to the thickness of the first material at this section being thinner relative to the remaining portion of the first material. Accordingly, the electric field may differ at this portion of the first material and, accordingly, this portion of the first material may break down quicker than the remaining portion of the first material. In order to decrease the electric field at this portion of the first material, the overall thickness of the first material may be increased. However, as a thickness of the first material on the first, second, and third vias increases, a likelihood that the first via and the third via are able to penetrate the walls of the trench may decrease (e.g., due to an interaction between the first material and the second material).

In order to enable the first and third vias to penetrate the wall of the trench while mitigating the effects of the interaction between the first and second material, the first and third vias may retain a quantity of the first material such that the first and third vias may penetrate the walls of the trench, but may also be isolated from the first contact and the second contact. The second via may be coupled with one of the first contact and the second contact. As the second via penetrates the floor of the trench, the second via may be configured not to interact with (e.g., may be configured to be isolated with respect to) the wall of the trench. Accordingly, a quantity of the first material surrounding the second via may be greater than the quantity of the first material associated with the first via and the third via. The other of the first contact and the second contact may be coupled with another inner via within the trench. Coupling the second via with the one of the first contact and the second contact may have advantages as compared to coupling the first contact or the second contact with the first via or the second via. For instance, as the first material surrounding the second via does not interact with the wall of the trench, a thickness still enabling of trench penetration may be used for the first material surrounding the second via while still meeting an electrical field constraint (e.g., having an electrical field within the first material below a threshold amount). Additionally, as the first and third vias are not coupled with the first or second contacts, early breakdown of the first materials surrounding the first and third vias may not affect signals at the first and second contacts.

FIGS. 3A and 3B illustrate examples of memory array trench schemes 300-a and 300-b that support folded staircase via routing for memory in accordance with examples as disclosed herein. Memory array trench schemes 300-a and 300-b may depict trenches within a memory array from a top view.

Memory array trench scheme 300-a may include trenches 305-a and 305-b, where second material 330-a may represent a material between trench 305-a and a trench adjacent to trench 305-a along a first direction, second material 330-b may represent a material between trenches 305-a and 305-b along the first direction, and second material 330-c may represent a material between trench 305-b and an a trench adjacent to trench 305-b along the first direction. Each trench may include multiple instances of a first material 315 that penetrates (e.g., punches through) a surface of the trench, such as a floor 320 of the trench, along a second direction. For instance, first materials 315-a and 315-c may penetrate a first wall and a second wall of the trench, respectively and first material 315-a may penetrate a floor 320-a of the trench. Each trench may also include multiple instances of staircase contacts 325. For instance, trench 305-a may include a pair of staircase contacts 325-b and 325-a adjacent to each other along the first direction and located along the third direction relative to first materials 315-a, 315-b, and 315-c.

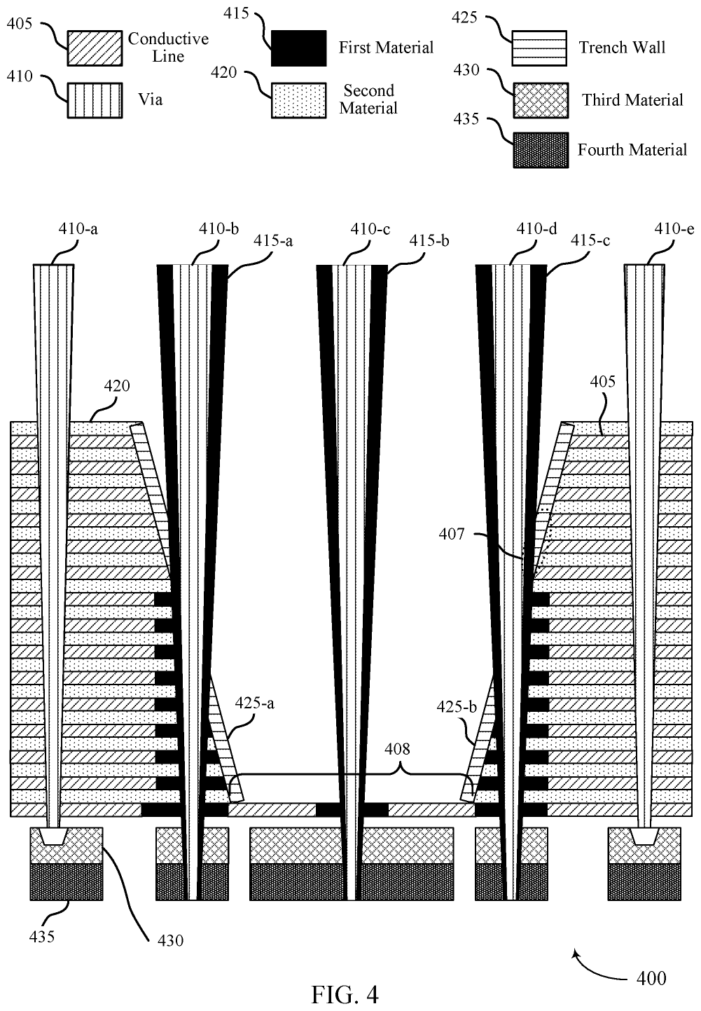

The multiple instances of the first material 315 may be grouped into groups of three and may be spaced along the trench in a third direction (e.g., a third direction perpendicular to the first and third direction) according to a predefined interval. Likewise, the multiple instances of the staircase contacts may be grouped into groups of two and may be spaced along the trench in the third direction according to the predefined interval. Each instance of the first material 315 may include a via. However, a subset of the instance of the first material 315 may include live vias 310, where a live via 310 may be defined as a vias that are coupled with a staircase contact 325. For instance, in the present example, via 310-a may be a live via that is coupled with a first of staircase contacts 325-a and 325-b and via 310-b may be a live via that is coupled with a second of staircase contacts 325-a and 325-b. The via of first material 315-b may be isolated from any staircase contacts (e.g., staircase contacts 325-a and 325-b) and may thus not be a live via 310 for memory array trench scheme 300-a. A side view of a trench is depicted herein, for instance, with reference to FIG. 4. In some cases, vias that penetrate a wall of a trench 305 may be referred to as outer vias (e.g., live vias 310-a and 310-b), whereas vias that penetrate the floor 320 of the trench 305 may be referred to as an inner via (e.g., the via of first material 315-b).

In some examples, each trench may be set up as a folded staircase. For instance, each grouping of staircase contacts may be on a lower level relative to the next or previous grouping along the third direction. Additionally, each staircase contact within the grouping may be on different levels relative to each other. The different levels may be formed as a result of performing a chop. Accordingly, the level of floor 320-a may vary along the third direction.

In some examples, each first material 315 may include a dielectric material that coats the respective via of the first material 315. The dielectric material may, for instance, be composed of an oxide liner. Each via of the first material 315 (e.g., each live via 310) may be composed of tungsten, titanium nitride, titanium, or any combination thereof. Each second material 330 may be composed of a conductive material, a nitride material, or any combination thereof. Each staircase contact 325 and/or the floor 320-a of trench 305-a may composed of a conductive material.

In some examples, the walls of trench may be coated in a third material (e.g., an oxide material) and floor 320-a may not be coated in the third material. Along some sections of the wall (e.g., where first materials 315-a and 315-c intersect with the wall), the third material may partially block the coating of the first material, which may affect the thickness of the first material for these sections. Accordingly, the electric field may vary along this portion of the walls and first materials 315-a and 315-c may break down more quickly along this portion of the walls relative to the other portions of first materials 315-a and 315-c. In order to increase the lifespan of first materials 315-a and 315-c along these portions of the walls, an overall thickness of first materials 315-a and 315-c may be increased. However, as a thickness of first materials 315-a and 315-c increases (e.g., to 85 nanometers), a likelihood that live vias 310-a and 310-b may be able to penetrate the walls of the trench may decrease (e.g., due to an interaction between first materials 315-a and 315-c with the walls of the trench).

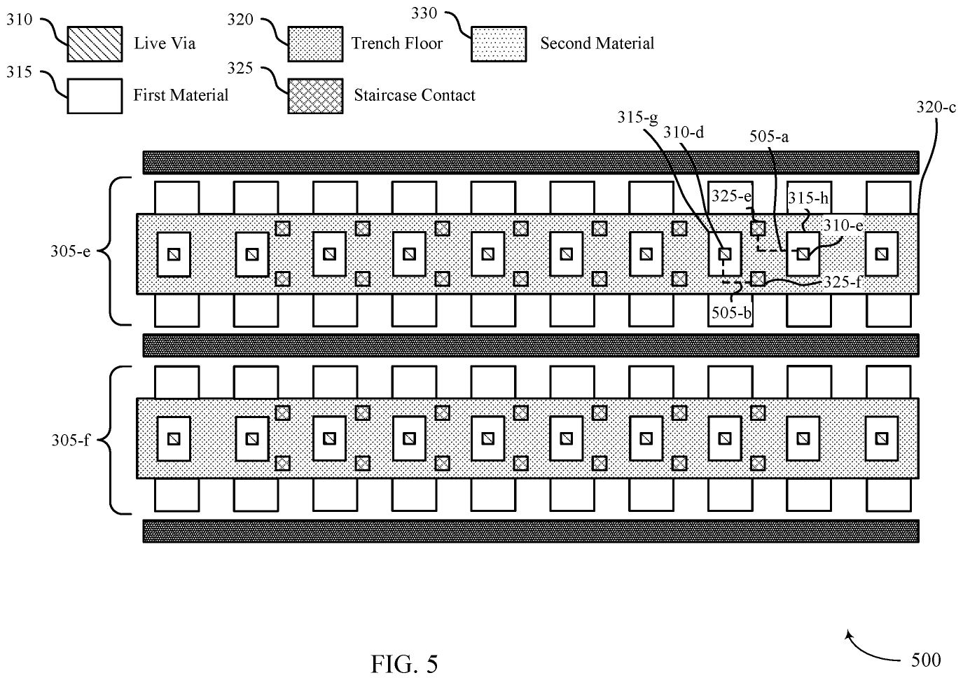

In order to enable live vias 310-a and 310-b to penetrate the walls of trench 305-a while mitigating the effects of the interaction between the first materials 315-a and 315-c with the third material coating the walls of the trench, first materials 315-a and 315-c may retain a thin enough coating of the first material such that live vias 310-a and 310-b may penetrate the walls of trench 305-a, but may also be isolated from staircase contacts 325-a and 325-b (that is, live vias 310-a and 310-b may no longer be live). Instead, the via of first material 315-b may be coupled with one of staircase contact 325-a and 325-b (e.g., the via of first material 315-b may become a live via 310). As the via of first material 315-b penetrates floor 320-a, the via of first material 315-b may not interact with the wall of trench 305-a. Accordingly, the thickness of first material 315-b may remain unadjusted (e.g., may remain at 65 nanometers). The other of staircase contacts 325-a and 325-b may be coupled with another inner via within trench 305-a. Additional details concerning coupling staircase contacts 325 with inner vias may be described herein, for instance, with reference to FIG. 5.

An example using an inner live via 310 is described with reference to FIG. 3B. Memory array trench scheme 300-b may include trenches 305-c and 305-d, where second material 330-d may represent a material between trench 305-c and a trench adjacent to trench 305-c along a first direction, second material 330-e may represent a material between trenches 305-c and 305-d along the first direction, and second material 330-f may represent a material between trench 305-d and an a trench adjacent to trench 305-d along the first direction. Each trench may include multiple instances of a first material 315 that penetrates a surface of the trench, such as a floor 320 of the trench, along a second direction. For instance, first materials 315-d and 315-f may penetrate a first wall and a second wall of the trench, respectively and first material 315-e may penetrate a floor 320-b of the trench. Each trench may also include multiple instances of staircase contacts 325. For instance, trench 305-c may include a pair of staircase contacts 325-c and 325-d adjacent to each other along the first direction and located along the third direction relative to first materials 315-d, 315-e, and 315-f.

The multiple instances of the first material 315 may be grouped into groups of three and may be spaced along the trench in a third direction (e.g., a third direction perpendicular to the first and third direction) according to a predefined interval. Likewise, the multiple instances of the staircase contacts 325 may be grouped into groups of two and may be spaced along the trench in the third direction according to the predefined interval. Each instance of the first material 315 may include a via. However, a subset of the instance of the first material 315 may include live vias 310, where a live via 310 may be defined as a vias that are coupled with a staircase contact 325. For instance, in the present example, via 310-e may be a live via that is coupled with one of staircase contacts 325-a and 325-b. The via of first materials 315-a and 315-c may be isolated from any staircase contacts (e.g., staircase contacts 325-c and 325-d) and may thus not be live vias 310 for memory array trench scheme 300-b. A side view of a trench is depicted herein, for instance, with reference to FIG. 4. In some cases, vias that penetrate a wall of a trench 305 may be referred to as outer vias (e.g., the vias of first materials 315-d and 315-f), whereas vias that penetrate the floor 320 of the trench 305 may be referred to as an inner via (e.g., the via of first material 315-e).

In some examples, each trench may be set up as a folded staircase. For instance, each grouping of staircase contacts may be on a lower level relative to the next or previous grouping along the third direction. Additionally, each staircase contact within the grouping may be on different levels relative to each other. Accordingly, the level of floor 320-b may vary along the third direction.

In some examples, each first material 315 may include a dielectric material that coats the respective via of the first material 315. The dielectric material may, for instance, be composed of an oxide liner. Each via of the first material 315 (e.g., each live via 310) may be composed of tungsten, titanium nitride, titanium, or any combination thereof. Each second material 330 may be composed of a conductive material, a nitride material, or any combination thereof. Each staircase contact 325 and/or the floor 320-b of trench 305-c may composed of a conductive material.

Because live via 310-c is an inner via, no interaction may occur between live via 310-c and a third material (e.g., an oxide material) on a surface of the walls of 305-c. Additionally, because the vias of first materials 315-d and 315-f are not live vias, thin enough first materials 315-d and 315-f may be used for penetrating the walls of trench 305-c. In some cases, the other of staircase contacts 325-c and 325-d may be coupled with another inner via within trench 305-c. Additional details concerning coupling staircase contacts 325 with inner vias may be described herein, for instance, with reference to FIG. 5.

FIG. 4 illustrates an example of a memory array trench diagram 400 that supports folded staircase via routing for memory in accordance with examples as disclosed herein. In some examples, memory array trench diagram 400 may represent a side vide of a memory array trench. In some examples, memory array trench diagram 400 may implement one or more aspects of memory array trench schemes 300-a and 300-b. For instance, first material 415-a may be an example of a first material 315-a or 315-d as described with reference to FIGS. 3A and 3B, first material 415-b may be an example of a first material 315-b or 315-e as described with reference to FIGS. 3A and 3B, and first material 415-c may be an example of a first material 315-c or 315-f as described with reference to FIGS. 3A and 3B. Additionally, trench floor 408 may be an example of a trench floor 320 as described with reference to FIGS. 3A and 3B. Additionally, vias 410-b and 410-d may be examples of live vias 310-a and 310-b as described with reference to FIG. 3A and/or via 410-c may be an example of live via 310-c as described with reference to FIG. 3B.

Memory array trench diagram 400 may include a trench composed of trench walls 425-a and 425-b as well as a trench floor 408 underneath trench walls 425-a and 425-b. Additionally, memory array trench diagram 400 may include a set of vias 410-a through 410-e, where via 410-b may penetrate trench wall 425-a, via 410-c may penetrate trench floor 408 (e.g., at a center of trench floor 408), and via 410-d may penetrate trench wall 425-b. Additionally, vias 410-b through 410-d may penetrate through third material 430 (e.g., a poly-silicon material) and fourth material 435 (e.g., a tungsten silicide material). In some examples, via 410-b may be coated in first material 415-a (e.g., a dielectric material, such as an oxide material), via 410-c may be coated in first material 415-b (e.g., a dielectric material, such as an oxide material), and via 410-d may be coated in first material 415-c (e.g., a dielectric material, such as an oxide material), where first material 415-a may penetrate trench wall 425-a, first material 415-b may penetrate trench floor 408, and first material 415-c may penetrate trench wall 425-b. In some examples, via 410-c may be coupled with a word line and/or vias 410-b and 410-d may be electrically isolated from a word line. Vias 410-a and 410-e may extend through multiple alternating layers of conductive lines 405 (e.g., row lines, word lines) and second material 420 (e.g., a nitride material) and may terminate at third material 430. In some examples, alternating recesses (e.g., alternating nitride recesses) may be present in first materials 415-a and 415-c in regions where first materials 415-a and 415-c come into contact with alternating conductive lines 405 and second materials 420 (e.g., after first materials 415-a and 415-c penetrate trench walls 425-a and 425-b), which may enable an improved tier collapse margin (e.g., through reduced tier nitride length). In some examples, some or each of the vias 410-a through 410-e may have a structural function (e.g., preventing collapse of one or more portions of the memory array).

In some examples, trench walls 425-a and 425-b may be coated in a wall material (e.g., an oxide material) and the floor 408 of the trench may not be coated in the wall material (e.g., the floor 408 of the trench may include the material of conductive lines 405 and first material 415). Along a region of trench walls 425-a and 425-b (e.g., region 407), the wall material may partially block the coating of first material 415 (e.g., first material 415-c). Accordingly, the thickness of the first material 415 (e.g., first material 415-c) in this region may be decreased relative to other regions of trench walls 425-a and 425-b (e.g., the areas below region 407). It should be noted that the thickness of first material 415 may be defined as the distance from the via of a first material 415 to a conductive line 405 along the first direction (e.g., the left-right direction in FIG. 4). Accordingly, the electric field may be increased (e.g., above 3.5 millivolts per centimeter for a 35v difference) along this region (e.g., region 407) and the portion of first material 415 associated with this region may break down more quickly. In order to increase the lifespan of the first materials 415 penetrating trench walls 425-a and 425-b, an overall thickness of first materials 415 penetrating trench walls 425-a and 425-b may be increased. However, as a thickness of these first materials 415 increases, a likelihood that the associated vias (vias 410-b and 410-d) may be able to penetrate trench walls 425-a and 425-b may decrease (e.g., due to an interaction between first materials 415-a and 415-c with trench walls 425-a and 425-b, respectively).

In order to enable trench walls 425-a and 425-b to be penetrated while mitigating the effects of the electric field in the region of decreased thickness for first materials penetrating a trench wall 425-b, first materials 415 may retain a thin enough coating of the first material such that vias 410-b and 410-d may penetrate trench walls 425-a and 425-b, but vias 410-b and 410-d may be isolated from staircase contacts of the trench. Instead, via 410-c may be coupled with a staircase contact of the trench. As first material 415-b does not interact with trench walls 425-a and 425-b, the thickness of first material 415-b may not be adjusted to compensate for the region of decreased thickness for first materials 415-a and 415-c (e.g., region 407).

In some examples, to form the trench, a portion of a region including alternating layers of conductive lines 405 and second material 420 may be chopped or etched, where conductive lines 405 extend in a first direction and the trench extends through the conductive lines 405 and the second material 420 in a second direction different than the first direction. After forming the trench, vias 410-b, 410-c, and 410-d may be formed in the trench. Additional sets of vias (e.g., aligned with vias 410-b, 410-c, and 410-d along a third direction different than the first direction and the second direction) may also be formed. In some examples, after forming the trench, staircase contacts may be formed on trench floor 408 (e.g., located along the third direction relative to via 410-c).

FIG. 5 illustrates an example of a memory array trench scheme 500 that supports folded staircase via routing for memory in accordance with examples as disclosed herein. In some examples, memory array trench scheme 500 may implement one or more aspects of memory array trench scheme 300-b. For instance, trenches 305-e and 305-f may be examples of a trench 305 as described with reference to FIG. 3B, first materials 315-g and 315-h may be examples of first materials 315 (e.g., first material 315-e) as described with reference to FIG. 3B, live vias 310-d and 310-e may be examples of live vias 310 (e.g., live via 310-c) as described with reference to FIG. 3B, staircase contacts 325- and 325-f may be examples of staircase contacts as described with reference to FIG. 3B, and floor 320-c may be an example of a trench floor as described with reference to FIG. 3B.

In examples in which inner vias include live vias 310, a first staircase contact 325 (e.g., staircase contact 325-e) may be coupled with a first inner via (e.g., live via 310-d via connection 505-b) and a second staircase contact 325 (e.g., staircase contact 325-f) may be coupled with a second inner via (e.g., live via 310-e via connection 505-a). In some examples, live via 310-e may be located in an adjacent crest and connection 505-a may be an example of mixed metal routing. In some examples, a staircase contact 325 associated with a middle chop may use an adjacent live via 310 for connection and a staircase contact 325 associated with a chop termination side may use a live via 310 of a crest for termination (e.g., the staircase contact 325 located higher up may be routed to a farther out region of trench 305-c as compared to the staircase contact 325 located lower down). Alternatively, an additional inner via may be included that penetrates the surface of the trench floor and that is adjacent to first material 315-g (e.g., along a first direction between which staircase contacts 325-e and 325-f are adjacent). In some examples, first material 315-g may be located in a folded staircase zone and first material 315-h may be located in a zone in which a folded staircase is not present.

FIG. 6 shows a block diagram 600 of a memory device 620 that supports folded staircase via routing for memory in accordance with examples as disclosed herein. The memory device 620 may be an example of aspects of a memory device as described with reference to FIGS. 1 through 5. The memory device 620, or various components thereof, may be an example of means for performing various aspects of folded staircase via routing for memory as described herein. For example, the memory device 620 may include a word line forming component 625, a trench forming component 630, a via forming component 635, a contact forming component 640, or any combination thereof. Each of these components may communicate, directly or indirectly, with one another (e.g., via one or more buses).

The word line forming component 625 may be configured as or otherwise support a means for forming a set of word lines that extend in a first direction. The trench forming component 630 may be configured as or otherwise support a means for forming a trench that extends through at least a portion of the set of word lines in a second direction different than the first direction. The via forming component 635 may be configured as or otherwise support a means for forming a first via, a second via, and a third via in the trench, where the first via, the second via, and the third via extend in the second direction, where the second via is between the first via and the third via along the first direction, where the second via is coupled with a word line of the set of word lines, and where the first via and the third via are electrically isolated from the word line of the set of word lines.

In some examples, the via forming component 635 may be configured as or otherwise support a means for forming a fourth via, a fifth via, and a sixth via in the trench, where the fourth via, the fifth via, and the sixth via extend in the second direction, where the fifth via is between the fourth via and the sixth via along the first direction, where the fifth via is coupled with a second word line of the set of word lines, where the fourth via and the sixth via are electrically isolated from the word line of the set of word lines, and where the first via is aligned with the fourth via along a third direction different than the first direction and the second direction, the second via is aligned with the fifth via along the third direction, and the third via is aligned with the sixth via along the third direction.

In some examples, the second via being coupled with the word line is based at least in part on a first material surrounding the second via contacting the trench at a first level of the trench along the second direction and the fifth via being coupled with the second word line is based at least in part on a second material surrounding the fifth via contacting the trench at a second level of the trench along the second direction different than the first level of the trench.

In some examples, the contact forming component 640 may be configured as or otherwise support a means for forming a first contact and a second contact on the trench, where the first contact and the second contact are aligned along the first direction, where the first contact contacts the trench at a first level of the trench along the second direction and the second contact contacts the trench at a second level of the trench along the second direction different than the first level of the trench, and where the first contact is coupled with the second via.

In some examples, the second contact is coupled with a fourth via. In some examples, the fourth via is aligned with the second via along a third direction different than the first direction and the second direction.

In some examples, the second via is surrounded by a dielectric material.

In some examples, the first via and the third via are surrounded by the dielectric material. In some examples, the first via and the third via are electrically isolated from the word line of the set of word lines based at least in part on a thickness of the dielectric material.

In some examples, the dielectric material includes an oxide material.

In some examples, the second via includes titanium, or titanium nitride, or tungsten, or any combination thereof.

FIG. 7 shows a flowchart illustrating a method 700 that supports folded staircase via routing for memory in accordance with examples as disclosed herein. The operations of method 700 may be implemented by a memory device or its components as described herein. For example, the operations of method 700 may be performed by a memory device as described with reference to FIGS. 1 through 6. In some examples, a memory device may execute a set of instructions to control the functional elements of the device to perform the described functions. Additionally, or alternatively, the memory device may perform aspects of the described functions using special-purpose hardware.

At 705, the method may include forming a set of word lines that extend in a first direction. The operations of 705 may be performed in accordance with examples as disclosed herein. In some examples, aspects of the operations of 705 may be performed by a word line forming component 625 as described with reference to FIG. 6.

At 710, the method may include forming a trench that extends through at least a portion of the set of word lines in a second direction different than the first direction. The operations of 710 may be performed in accordance with examples as disclosed herein. In some examples, aspects of the operations of 710 may be performed by a trench forming component 630 as described with reference to FIG. 6.

At 715, the method may include forming a first via, a second via, and a third via in the trench, where the first via, the second via, and the third via extend in the second direction, where the second via is between the first via and the third via along the first direction, where the second via is coupled with a word line of the set of word lines, and where the first via and the third via are electrically isolated from the word line of the set of word lines. The operations of 715 may be performed in accordance with examples as disclosed herein. In some examples, aspects of the operations of 715 may be performed by a via forming component 635 as described with reference to FIG. 6.

In some examples, an apparatus as described herein may perform a method or methods, such as the method 700. The apparatus may include features, circuitry, logic, means, or instructions (e.g., a non-transitory computer-readable medium storing instructions executable by a processor), or any combination thereof for performing the following aspects of the present disclosure:

Aspect 1: A method, apparatus, or non-transitory computer-readable medium including operations, features, circuitry, logic, means, or instructions, or any combination thereof for forming a set of word lines that extend in a first direction; forming a trench that extends through at least a portion of the set of word lines in a second direction different than the first direction; and forming a first via, a second via, and a third via in the trench, where the first via, the second via, and the third via extend in the second direction, where the second via is between the first via and the third via along the first direction, where the second via is coupled with a word line of the set of word lines, and where the first via and the third via are electrically isolated from the word line of the set of word lines.

Aspect 2: The method, apparatus, or non-transitory computer-readable medium of aspect 1, further including operations, features, circuitry, logic, means, or instructions, or any combination thereof for forming a fourth via, a fifth via, and a sixth via in the trench, where the fourth via, the fifth via, and the sixth via extend in the second direction, where the fifth via is between the fourth via and the sixth via along the first direction, where the fifth via is coupled with a second word line of the set of word lines, where the fourth via and the sixth via are electrically isolated from the word line of the set of word lines, and where the first via is aligned with the fourth via along a third direction different than the first direction and the second direction, the second via is aligned with the fifth via along the third direction, and the third via is aligned with the sixth via along the third direction.

Aspect 3: The method, apparatus, or non-transitory computer-readable medium of aspect 2, where the second via being coupled with the word line is based at least in part on a first material surrounding the second via contacting the trench at a first level of the trench along the second direction and the fifth via being coupled with the second word line is based at least in part on a second material surrounding the fifth via contacting the trench at a second level of the trench along the second direction different than the first level of the trench.

Aspect 4: The method, apparatus, or non-transitory computer-readable medium of any of aspects 1 through 3, further including operations, features, circuitry, logic, means, or instructions, or any combination thereof for forming a first contact and a second contact on the trench, where the first contact and the second contact are aligned along the first direction, where the first contact contacts the trench at a first level of the trench along the second direction and the second contact contacts the trench at a second level of the trench along the second direction different than the first level of the trench, and where the first contact is coupled with the second via.

Aspect 5: The method, apparatus, or non-transitory computer-readable medium of aspect 4, where the second contact is coupled with a fourth via and the fourth via is aligned with the second via along a third direction different than the first direction and the second direction.

Aspect 6: The method, apparatus, or non-transitory computer-readable medium of any of aspects 1 through 5, where the second via is surrounded by a dielectric material.

Aspect 7: The method, apparatus, or non-transitory computer-readable medium of aspect 6, where the first via and the third via are surrounded by the dielectric material and the first via and the third via are electrically isolated from the word line of the set of word lines based at least in part on a thickness of the dielectric material.

Aspect 8: The method, apparatus, or non-transitory computer-readable medium of any of aspects 6 through 7, where the dielectric material includes an oxide material.

Aspect 9: The method, apparatus, or non-transitory computer-readable medium of any of aspects 1 through 8, where the second via includes titanium, or titanium nitride, or tungsten, or any combination thereof.

It should be noted that the described techniques include possible implementations, and that the operations and the steps may be rearranged or otherwise modified and that other implementations are possible. Further, portions from two or more of the methods may be combined.

An apparatus is described. The following provides an overview of aspects of the apparatus as described herein:

Aspect 10: An apparatus, including: a set of word lines extending in a first direction; and a first via, a second via, and a third via in a trench that extends through at least a portion of the set of word lines, where the first via, the second via, and the third via extend in a second direction different than the first, where the second via is between the first via and the third via along the first direction, where the second via is coupled with a word line of the set of word lines, and where the first via and the third via are electrically isolated from the word line of the set of word lines.

Aspect 11: The apparatus of aspect 10, further including: a fourth via, a fifth via, and a sixth via in the trench, where the fourth via, the fifth via, and the sixth via extend in the second direction, where the fifth via is between the fourth via and the sixth via along the first direction, where the fifth via is coupled with a second word line of the set of word lines, where the fourth via and the sixth via are electrically isolated from the word line of the set of word lines, and where the first via is aligned with the fourth via along a third direction different than the first direction and the second direction, the second via is aligned with the fifth via along the third direction, and the third via is aligned with the sixth via along the third direction.

Aspect 12: The apparatus of aspect 11, where the second via being coupled with the word line is based at least in part on a first material surrounding the second via contacting the trench at a first level of the trench along the second direction and the fifth via being coupled with the second word line is based at least in part on a second material surrounding the fifth via contacting the trench at a second level of the trench along the second direction different than the first level of the trench.

Aspect 13: The apparatus of any of aspects 10 through 12, further including: a first contact and a second contact on the trench, where the first contact and the second contact are aligned along the first direction, where the first contact contacts the trench at a first level of the trench along the second direction and the second contact contacts the trench at a second level of the trench along the second direction different than the first level of the trench, and where the first contact is coupled with the second via.

Aspect 14: The apparatus of aspect 13, where the second contact is coupled with a fourth via, the fourth via is aligned with the second via along a third direction different than the first direction and the second direction.

Aspect 15: The apparatus of any of aspects 10 through 14, where second via is surrounded by a dielectric material.

Aspect 16: The apparatus of aspect 15, where the first via and the third via are surrounded by the dielectric material, the first via and the third via are electrically isolated from the word line of the set of word lines based at least in part on a thickness of the dielectric material.

Aspect 17: The apparatus of any of aspects 15 through 16, where the dielectric material includes an oxide material.

Aspect 18: The apparatus of any of aspects 10 through 17, where the second via includes titanium, or titanium nitride, or tungsten, or any combination thereof.

An apparatus is described. The following provides an overview of aspects of the apparatus as described herein:

Aspect 19: An apparatus, including: a set of word lines extending in a first direction; a trench through at least a portion of the set of word lines and that extends in a second direction different than the first direction; and a plurality of vias in the trench, where each via of the plurality extends in the second direction, where a first via of the plurality of vias is electrically isolated from a word line of the set of word lines, and where a second via of the plurality of vias extends through a center of the trench and is coupled with the word line of the set of word lines.

Aspect 20: The apparatus of aspect 19, further including: a second plurality of vias in the trench, where each via of the second plurality extends in the second direction, where a third via of the plurality of vias is electrically isolated from a second word line of the set of word lines, and where a fourth via of the plurality of vias extends through the center of the trench and is coupled with the second word line of the set of word lines.

Aspect 21: The apparatus of aspect 20, where the second via being coupled with the word line and the fourth via being coupled with the second word line is based at least in part on the second via and the fourth via being associated with different levels of the trench.

Aspect 22: The apparatus of any of aspects 19 through 21, further including: a contact on the trench, where the contact is coupled with the second via.

Aspect 23: The apparatus of aspect 22, further including: a second contact on the trench, where the second contact is aligned with the contact along the first direction, and where the second contact is coupled with a third via, where the third via is aligned with the second via along a third direction different than the first direction and the second direction.

Aspect 24: The apparatus of any of aspects 19 through 23, where each of the plurality of vias is surrounded by includes a dielectric material.

Information and signals described herein may be represented using any of a variety of different technologies and techniques. For example, data, instructions, commands, information, signals, bits, symbols, and chips that may be referenced throughout the description may be represented by voltages, currents, electromagnetic waves, magnetic fields or particles, optical fields or particles, or any combination thereof. Some drawings may illustrate signals as a single signal; however, the signal may represent a bus of signals, where the bus may have a variety of bit widths.

The terms “electronic communication,” “conductive contact,” “connected,” and “coupled” may refer to a relationship between components that supports the flow of signals between the components. Components are considered in electronic communication with (or in conductive contact with or connected with or coupled with) one another if there is any conductive path between the components that can, at any time, support the flow of signals between the components. At any given time, the conductive path between components that are in electronic communication with each other (or in conductive contact with or connected with or coupled with) may be an open circuit or a closed circuit based on the operation of the device that includes the connected components. The conductive path between connected components may be a direct conductive path between the components or the conductive path between connected components may be an indirect conductive path that may include intermediate components, such as switches, transistors, or other components. In some examples, the flow of signals between the connected components may be interrupted for a time, for example, using one or more intermediate components such as switches or transistors.

The term “coupling” refers to a condition of moving from an open-circuit relationship between components in which signals are not presently capable of being communicated between the components over a conductive path to a closed-circuit relationship between components in which signals are capable of being communicated between components over the conductive path. If a component, such as a controller, couples other components together, the component initiates a change that allows signals to flow between the other components over a conductive path that previously did not permit signals to flow.

The term “isolated” refers to a relationship between components in which signals are not presently capable of flowing between the components. Components are isolated from each other if there is an open circuit between them. For example, two components separated by a switch that is positioned between the components are isolated from each other if the switch is open. If a controller isolates two components, the controller affects a change that prevents signals from flowing between the components using a conductive path that previously permitted signals to flow.

The term “layer” or “level” used herein refers to a stratum or sheet of a geometrical structure (e.g., relative to a substrate). Each layer or level may have three dimensions (e.g., height, width, and depth) and may cover at least a portion of a surface. For example, a layer or level may be a three dimensional structure where two dimensions are greater than a third, e.g., a thin-film. Layers or levels may include different elements, components, and/or materials. In some examples, one layer or level may be composed of two or more sublayers or sublevels.

As used herein, the term “electrode” may refer to an electrical conductor, and in some examples, may be employed as an electrical contact to a memory cell or other component of a memory array. An electrode may include a trace, wire, conductive line, conductive layer, or the like that provides a conductive path between elements or components of a memory array.

The terms “if,” “when,” “based on,” or “based at least in part on” may be used interchangeably. In some examples, if the terms “if,” “when,” “based on,” or “based at least in part on” are used to describe a conditional action, a conditional process, or connection between portions of a process, the terms may be interchangeable.

The devices discussed herein, including a memory array, may be formed on a semiconductor substrate, such as silicon, germanium, silicon-germanium alloy, gallium arsenide, gallium nitride, etc. In some examples, the substrate is a semiconductor wafer. In some other examples, the substrate may be a silicon-on-insulator (SOI) substrate, such as silicon-on-glass (SOG) or silicon-on-sapphire (SOP), or epitaxial layers of semiconductor materials on another substrate. The conductivity of the substrate, or sub-regions of the substrate, may be controlled through doping using various chemical species including, but not limited to, phosphorous, boron, or arsenic. Doping may be performed during the initial formation or growth of the substrate, by ion-implantation, or by any other doping means.

A switching component or a transistor discussed herein may represent a field-effect transistor (FET) and comprise a three terminal device including a source, drain, and gate. The terminals may be connected to other electronic elements through conductive materials, e.g., metals. The source and drain may be conductive and may comprise a heavily-doped, e.g., degenerate, semiconductor region. The source and drain may be separated by a lightly-doped semiconductor region or channel. If the channel is n-type (i.e., majority carriers are electrons), then the FET may be referred to as an n-type FET. If the channel is p-type (i.e., majority carriers are holes), then the FET may be referred to as a p-type FET. The channel may be capped by an insulating gate oxide. The channel conductivity may be controlled by applying a voltage to the gate. For example, applying a positive voltage or negative voltage to an n-type FET or a p-type FET, respectively, may result in the channel becoming conductive. A transistor may be “on” or “activated” if a voltage greater than or equal to the transistor's threshold voltage is applied to the transistor gate. The transistor may be “off” or “deactivated” if a voltage less than the transistor's threshold voltage is applied to the transistor gate.

The description set forth herein, in connection with the appended drawings, describes example configurations and does not represent all the examples that may be implemented or that are within the scope of the claims. The term “exemplary” used herein means “serving as an example, instance, or illustration” and not “preferred” or “advantageous over other examples.” The detailed description includes specific details to provide an understanding of the described techniques. These techniques, however, may be practiced without these specific details. In some instances, well-known structures and devices are shown in block diagram form to avoid obscuring the concepts of the described examples.

In the appended figures, similar components or features may have the same reference label. Further, various components of the same type may be distinguished by following the reference label by a hyphen and a second label that distinguishes among the similar components. If just the first reference label is used in the specification, the description is applicable to any one of the similar components having the same first reference label irrespective of the second reference label.

The functions described herein may be implemented in hardware, software executed by a processor, firmware, or any combination thereof. If implemented in software executed by a processor, the functions may be stored on or transmitted over, as one or more instructions or code, a computer-readable medium. Other examples and implementations are within the scope of the disclosure and appended claims. For example, due to the nature of software, the described functions can be implemented using software executed by a processor, hardware, firmware, hardwiring, or combinations of any of these. Features implementing functions may also be physically located at various positions, including being distributed such that portions of functions are implemented at different physical locations.

For example, the various illustrative blocks and components described in connection with the disclosure herein may be implemented or performed with a general-purpose processor, a DSP, an ASIC, an FPGA or other programmable logic device, discrete gate or transistor logic, discrete hardware components, or any combination thereof designed to perform the functions described herein. A general-purpose processor may be a microprocessor, but in the alternative, the processor may be any processor, controller, microcontroller, or state machine. A processor may be implemented as a combination of computing devices (e.g., a combination of a DSP and a microprocessor, multiple microprocessors, one or more microprocessors in conjunction with a DSP core, or any other such configuration).

As used herein, including in the claims, “or” as used in a list of items (for example, a list of items prefaced by a phrase such as “at least one of” or “one or more of”) indicates an inclusive list such that, for example, a list of at least one of A, B, or C means A or B or C or AB or AC or BC or ABC (i.e., A and B and C). Also, as used herein, the phrase “based on” shall not be construed as a reference to a closed set of conditions. For example, an exemplary step that is described as “based on condition A” may be based on both a condition A and a condition B without departing from the scope of the present disclosure. In other words, as used herein, the phrase “based on” shall be construed in the same manner as the phrase “based at least in part on.”

Computer-readable media includes both non-transitory computer storage media and communication media including any medium that facilitates transfer of a computer program from one place to another. A non-transitory storage medium may be any available medium that can be accessed by a general purpose or special purpose computer. By way of example, and not limitation, non-transitory computer-readable media can comprise RAM, ROM, electrically erasable programmable read-only memory (EEPROM), compact disk (CD) ROM or other optical disk storage, magnetic disk storage or other magnetic storage devices, or any other non-transitory medium that can be used to carry or store desired program code means in the form of instructions or data structures and that can be accessed by a general-purpose or special-purpose computer, or a general-purpose or special-purpose processor. Also, any connection is properly termed a computer-readable medium. For example, if the software is transmitted from a website, server, or other remote source using a coaxial cable, fiber optic cable, twisted pair, digital subscriber line (DSL), or wireless technologies such as infrared, radio, and microwave, then the coaxial cable, fiber optic cable, twisted pair, DSL, or wireless technologies such as infrared, radio, and microwave are included in the definition of medium. Disk and disc, as used herein, include CD, laser disc, optical disc, digital versatile disc (DVD), floppy disk, and Blu-ray disc, where disks usually reproduce data magnetically, while discs reproduce data optically with lasers. Combinations of these are also included within the scope of computer-readable media.

The description herein is provided to enable a person skilled in the art to make or use the disclosure. Various modifications to the disclosure will be apparent to those skilled in the art, and the generic principles defined herein may be applied to other variations without departing from the scope of the disclosure. Thus, the disclosure is not limited to the examples and designs described herein but is to be accorded the broadest scope consistent with the principles and novel features disclosed herein.

What is claimed is:

1. A method, comprising:
forming a set of word lines that extend in a first direction;
forming a trench that extends through at least a portion of the set of word lines in a second direction different than the first direction; and
forming a first via, a second via, and a third via in the trench, wherein the first via, the second via, and the third via extend in the second direction, wherein the second via is between the first via and the third via along the first direction, wherein the second via is coupled with a word line of the set of word lines, and wherein the first via and the third via are electrically isolated from the word line of the set of word lines.

2. The method of claim 1, further comprising:
forming a fourth via, a fifth via, and a sixth via in the trench, wherein the fourth via, the fifth via, and the sixth via extend in the second direction, wherein the fifth via is between the fourth via and the sixth via along the first direction, wherein the fifth via is coupled with a second word line of the set of word lines, wherein the fourth via and the sixth via are electrically isolated from the word line of the set of word lines, and wherein the first via is aligned with the fourth via along a third direction different than the first direction and the second direction, the second via is aligned with the fifth via along the third direction, and the third via is aligned with the sixth via along the third direction.

3. The method of claim 2, wherein the second via being coupled with the word line is based at least in part on a first material surrounding the second via contacting the trench at a first level of the trench along the second direction and the fifth via being coupled with the second word line is based at least in part on a second material surrounding the fifth via contacting the trench at a second level of the trench along the second direction different than the first level of the trench.

4. The method of claim 1, further comprising:
forming a first contact and a second contact on the trench, wherein the first contact and the second contact are aligned along the first direction, wherein the first contact contacts the trench at a first level of the trench along the second direction and the second contact contacts the trench at a second level of the trench along the second direction different than the first level of the trench, and wherein the first contact is coupled with the second via.

5. The method of claim 4, wherein:
the second contact is coupled with a fourth via, and
the fourth via is aligned with the second via along a third direction different than the first direction and the second direction.

6. The method of claim 1, wherein the second via is surrounded by a dielectric material.

7. The method of claim 6, wherein:
the first via and the third via are surrounded by the dielectric material, and
the first via and the third via are electrically isolated from the word line of the set of word lines based at least in part on a thickness of the dielectric material.

8. The method of claim 6, wherein the dielectric material comprises an oxide material.

9. The method of claim 1, wherein the second via comprises titanium, or
titanium nitride, or tungsten, or any combination thereof.

10. An apparatus, comprising:
a set of word lines extending in a first direction; and
a first via, a second via, and a third via in a trench that extends through at least a portion of the set of word lines, wherein the first via, the second via, and the third via extend in a second direction different than the first, wherein the second via is between the first via and the third via along the first direction, wherein the second via is coupled with a word line of the set of word lines, and wherein the first via and the third via are electrically isolated from the word line of the set of word lines.

11. The apparatus of claim 10, further comprising:
a fourth via, a fifth via, and a sixth via in the trench, wherein the fourth via, the fifth via, and the sixth via extend in the second direction, wherein the fifth via is between the fourth via and the sixth via along the first direction, wherein the fifth via is coupled with a second word line of the set of word lines, wherein the fourth via and the sixth via are electrically isolated from the word line of the set of word lines, and wherein the first via is aligned with the fourth via along a third direction different than the first direction and the second direction, the second via is aligned with the fifth via along the third direction, and the third via is aligned with the sixth via along the third direction.

12. The apparatus of claim 11, wherein the second via being coupled with the word line is based at least in part on a first material surrounding the second via contacting the trench at a first level of the trench along the second direction and the fifth via being coupled with the second word line is based at least in part on a second material surrounding the fifth via contacting the trench at a second level of the trench along the second direction different than the first level of the trench.

13. The apparatus of claim 10, further comprising:
a first contact and a second contact on the trench, wherein the first contact and the second contact are aligned along the first direction, wherein the first contact contacts the trench at a first level of the trench along the second direction and the second contact contacts the trench at a second level of the trench along the second direction different than the first level of the trench, and wherein the first contact is coupled with the second via.

14. The apparatus of claim 13, wherein:
the second contact is coupled with a fourth via, and
the fourth via is aligned with the second via along a third direction different than the first direction and the second direction.

15. The apparatus of claim 10, wherein second via is surrounded by a dielectric material.

16. The apparatus of claim 15, wherein:
the first via and the third via are surrounded by the dielectric material, and
the first via and the third via are electrically isolated from the word line of the set of word lines based at least in part on a thickness of the dielectric material.

17. The apparatus of claim 15, wherein the dielectric material comprises an oxide material.

18. The apparatus of claim 10, wherein the second via comprises titanium, or titanium nitride, or tungsten, or any combination thereof.

19. An apparatus, comprising:
a set of word lines extending in a first direction;
a trench through at least a portion of the set of word lines and that extends in a second direction different than the first direction; and
a plurality of vias in the trench, wherein each via of the plurality extends in the second direction, wherein a first via of the plurality of vias is electrically isolated from a word line of the set of word lines, and wherein a second via of the plurality of vias extends through a center of the trench and is coupled with the word line of the set of word lines.

20. The apparatus of claim 19, further comprising:
a second plurality of vias in the trench, wherein each via of the second plurality extends in the second direction, wherein a third via of the plurality of vias is electrically isolated from a second word line of the set of word lines, and wherein a fourth via of the plurality of vias extends through the center of the trench and is coupled with the second word line of the set of word lines.

21. The apparatus of claim 20, wherein the second via being coupled with the word line and the fourth via being coupled with the second word line is based at least in part on the second via and the fourth via being associated with different levels of the trench.

22. The apparatus of claim 19, further comprising:
a contact on the trench, wherein the contact is coupled with the second via.

23. The apparatus of claim 22, further comprising:
a second contact on the trench, wherein the second contact is aligned with the contact along the first direction, and wherein the second contact is coupled with a third via, wherein the third via is aligned with the second via along a third direction different than the first direction and the second direction.

24. The apparatus of claim 19, wherein each of the plurality of vias is surrounded by comprises a dielectric material.

25. The apparatus of claim 24, wherein each via of the plurality of vias comprises titanium, or titanium nitride, or tungsten, or any combination thereof.
